(19) United States
(12) Patent Application Publication
(10) Pub. No.: US 2005/0070048 A1
(43) Pub. Date: Mar. 31, 2005

(54) Devices and methods employing high thermal conductivity heat dissipation substrates

(76) Inventors: Peter G. Tolchinsky, Beaverton, OR (US); Mohamad A. Shaheen, Portland, OR (US); Irwin Yablok, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/672,968

(22) Filed: Sep. 25, 2003

(51) Int. Cl. H01L 21/48

(52) U.S. Cl. 438/108

(57) ABSTRACT

Embodiments of the present invention propose a bulk heat dissipation substrate that is part of the substrate on which the devices of an integrated circuit are formed. The bulk layer is formed directly under the device layer of a semiconductor substrate and has a thermal conductivity greater than that of the semiconductor substrate. It is a simple passive technique for the removal of heat during device operation. It is also very effective at the removal of heat from hot spots, or areas of excessive heat, because the heat dissipation material is in direct contact with the substrate on which the devices are formed. Such a material is also valuable for the dissipation of heat during the processing of the wafer substrate because it can be coupled to the semiconductor wafer before processing.

### BACKGROUND OF THE INVENTION

1. Field of the Invention

The present invention relates to the field of semiconductor processing, and more specifically to the dissipation of heat from a device substrate during processing and subsequent use of a device.

2. Discussion of Related Art

The dimensions of devices are shrinking in the integrated circuit (IC) industry while at the same time the number of devices and their respective operations is increasing. All of these factors add to an increase in the heat production of semiconductor devices and the formation of “hot spots”, or areas of intense heat, that develop on an IC during operation. Therefore, effective heat dissipation has become critical in order to further scale down devices and increase their numbers and operations.

Various techniques can typically be used to dissipate the heat generated by the operations of the devices on an IC die. One such technique is the use of a heat sink. As illustrated by the cross sectional view in FIG. 1, a heat sink 110 is a cap formed of a heat conductive material, such as copper, aluminum, or a ceramic, that is placed above and around an IC die 120 after processing. The heat sink is not in direct contact with the devices on the IC die because they are pointed down and away from the heat sink. Also, the heat sink is not in direct contact with the silicon substrate on which the devices of the IC die are formed because a first thermal interface material (TIM) 130 is placed between the backside of the IC die 110 and the heat sink 120. A TIM can be a thermally conductive gel, solder, or grease. A heat spreader 140 is typically also used for heat dissipation. The heat spreader 140 typically has fins 145 that increase the surface area of the spreader and thus further dissipate heat. Between the heat sink 120 and the heat spreader 140 a second TIM 150 is placed.

The heat produced by an IC die has exceeded the heat dissipation capacity of most passive heat sinks and heat spreaders such as the ones described above. Non-passive heat dissipation devices are being employed to further dissipate heat. One such device is a small cooling fan that can be part of the microelectronic package housing the IC die and the heat sink. Cooling fans can only dissipate a limited amount of heat without becoming unduly large and typically dissipate heat only from the microelectronic package and not from the IC die where the heat is produced.

Another non-passive cooling technique is a water-cooling system. Typically, a water-cooling system transfers heat from the heat sink and heat spreader within the microelectronic package. The hot water formed by this technique is pumped away and continually replaced with cooler water to dissipate heat. The water can run through a series of pipes around the heat sink or through the heat sink. Again, this technique can only dissipate a limited amount of heat before becoming bulky and mainly removes heat from the microelectronic package and not the IC die itself. Also, it creates the risk of destroying the electronics if the water comes into contact with the IC die and the surrounding microelectronic devices on a circuit board.

To avoid the use of bulky passive and non-passive cooling devices that are limited in their ability to dissipate heat, the industry has turned to the use of a heat dissipation layer that can be formed as part of the wafer on which the devices are formed. One such wafer features a thin diamond layer on a semiconductor wafer. A thin diamond layer having a thickness of between around 50-100 μm has a thermal conductivity that is greater than that of silicon. Heat can be dissipated more effectively by forming the thin diamond layer directly under the semiconductor wafer on which devices are formed. Additionally, the diamond layer can serve as a heat transfer layer from the semiconductor wafer, under which it is formed, to a bulk silicon substrate directly bonded to the opposite side of the thin diamond layer. But, when used in combination with a bulk silicon substrate, the effectiveness of the heat dissipation by the diamond layer is reduced. Additionally, diamond is an expensive material and it is limited to use as a thin film because its thermal conductivity decreases to a value less than the thermal conductivity of silicon when the diamond layer has a thickness greater than around 100 μm.

### BRIEF DESCRIPTION OF THE DRAWINGS

FIG. 1 is an illustration of a cross-sectional view of a prior art heat dissipation microelectronic package housing the IC die.

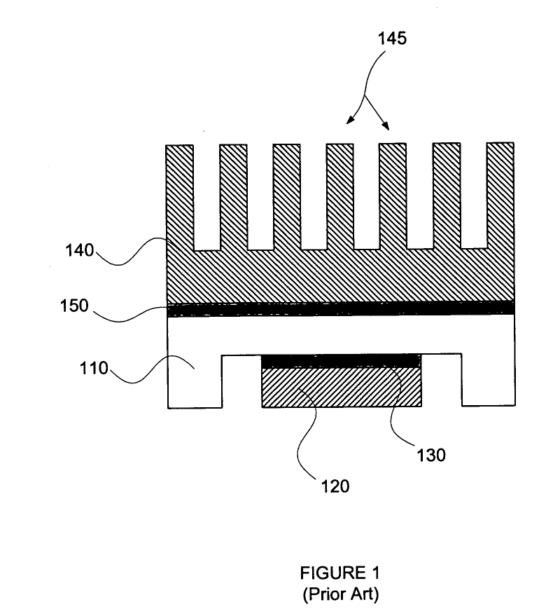

FIG. 2a is an illustration of a side view of a substrate comprising a silicon wafer and a heat dissipation wafer.

FIG. 2b is an illustration of a side view of a substrate comprising a silicon wafer, a transition layer, and a heat dissipation wafer.

FIG. 3a is an illustration of a side view of a substrate comprising a silicon wafer directly bonded to a silicon carbide wafer having a rough surface.

FIG. 3b is an illustration of a side view of a substrate comprising a silicon wafer bonded to a planarized transition layer on a silicon carbide wafer having a rough surface.

FIG. 4a is an illustration of the flow of forming a heat dissipation substrate by depositing a bulk heat dissipation layer on a semiconductor wafer.

FIG. 4b is an illustration of the flow of forming a heat dissipation substrate that includes a transition layer.

FIG. 4c is a flow diagram illustrating the bond and split method of forming a substrate comprising a silicon wafer and a silicon carbide wafer having a transition layer.

FIG. 4d is a side-view illustrating the Van der Walls forces between a silicon carbide wafer and a polysilicon transition layer.

FIG. 4e is a side-view illustrating the formation of covalent bonds between a silicon carbide wafer and a polysilicon transition layer.

FIG. 4f is a flow diagram illustrating the bond and grind back method.

FIG. 4g is a flow diagram illustrating an embodiment of forming a heat dissipation substrate.

FIG. 5a is an illustration of a wafer patterned into dies.

FIG. 5b is an illustration of a system comprising a heat dissipation microelectronic package housing the IC die, where the die is made with a substrate comprising silicon and a silicon carbide heat dissipation layer.

### DETAILED DESCRIPTION OF THE PRESENT INVENTION

Described herein are methods and devices employing a bulk layer of a high thermal conductivity heat dissipation substrate. In the following description numerous specific details are set forth. One of ordinary skill in the art, however, will appreciate that these specific details are not necessary to practice embodiments of the invention. While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art. In other instances, well known semiconductor fabrication processes, techniques, materials, equipment, etc., have not been set forth in particular detail in order to not unnecessarily obscure embodiments of the present invention.

Embodiments of the present invention propose a bulk heat dissipation layer that is part of the substrate on which the devices of an integrated circuit are formed. The bulk layer is formed under the device layer of a semiconductor substrate and has a thermal conductivity greater than that of the semiconductor substrate. It is a simple passive technique for the removal of heat during device operation. It is also very effective at the removal of heat from hot spots, or areas of excessive heat, because the heat dissipation material is in direct contact with the substrate on which the devices are formed. Such a material is also valuable for the dissipation of heat during the processing of the wafer substrate because it can be coupled to the semiconductor wafer before processing.

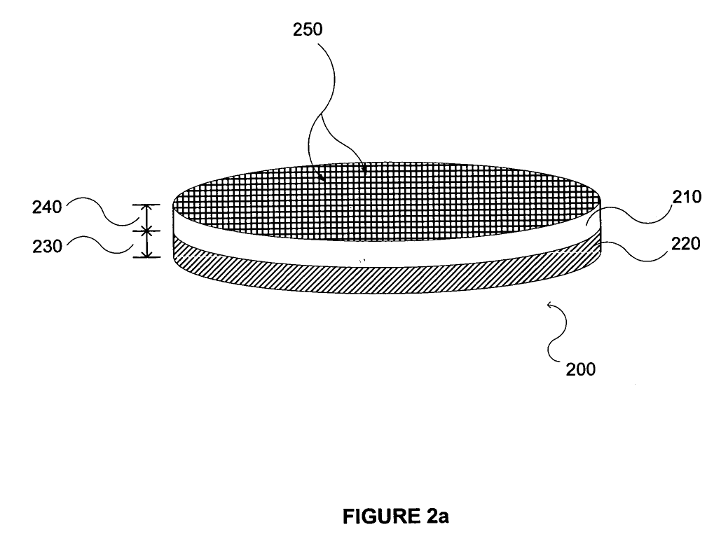

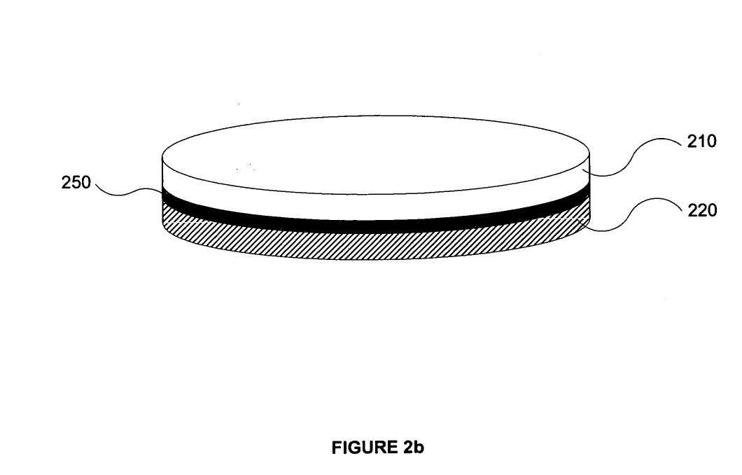

In an embodiment of the present invention, illustrated in FIG. 2a, a novel substrate 200 comprises a semiconductor layer 210 coupled to a bulk heat dissipation layer 220. The semiconductor layer can be a material well known in the art such as device quality silicon (Si), germanium (Ge), silicon on insulator (SOI), silicon on sapphire (SOS), or gallium arsenide (GaAs). In an embodiment the semiconductor layer is epitaxial or monocrystalline silicon. The bulk heat dissipation layer 220 can be any “bulk” layer of material that has a thermal conductivity (κ) that is higher than that of the semiconductor layer 210. Thermal conductivity is the quantity of heat that passes in a unit of time through a unit of an area of a plate of a unit of a thickness, when the opposite faces of the unit area and unit thickness differ in temperature by one degree. The thermal conductivity is measured in Watts per meter Celsius (W/m·C). The thermal conductivity of the bulk heat dissipation layer can be in the approximate range of 100 W/m·C to 2000 W/m·C depending on the material used as the bulk heat dissipation layer 220. If the bulk heat dissipation layer 220 is CVD silicon carbide, the range of thermal conductivity can be in the approximate range of 250 W/m·C to 300 W/m·C. A bulk heat dissipation layer is one that has a thickness greater than around 100 μm. Examples of bulk heat dissipation layer materials are silicon carbide (SiC), beryllium oxide (BeO₂), graphite, etc. In an embodiment, the thickness 230 of the bulk heat dissipation layer may be such that the thickness of the entire substrate comprising both the bulk heat dissipation layer 220 and the semiconductor layer 210 is still compatible for use in processing tools used in manufacturing. In the current state of the art, an example of a thickness for the semiconductor layer of a 300 mm wafer substrate is between 750 μm and 800 μm and the thickness of a bulk heat dissipation layer is also between 750 μm and 800 μm. This substrate can then be processed to form integrated circuits on the device quality semiconductor layer by forming transistors and other devices and connecting those devices by interconnects. The integrated circuits can then be cut into dies 250 that can become part of a package sold to consumers.

In an embodiment, the bulk heat dissipation layer is silicon carbide deposited by chemical vapor deposition, or CVD SiC. CVD SiC is the typical type of SiC employed because its properties are very similar to those of single crystal SiC. CVD SiC is a polycrystalline material, but it is mainly comprised of a cubic crystal lattice similar to that of diamond. The properties of CVD SiC are valuable for use as a bulk layer heat dissipation material. In particular, bulk CVD SiC has a higher thermal conductivity than semiconductor substrates used to produce devices. For example, at 26.84° C. CVD SiC has a thermal conductivity of 250-350 W/m·C and silicon has a thermal conductivity at 26.84° C. of 150 W/m·C. Additionally, CVD SiC is among the hardest known ceramics and it retains its hardness and strength at elevated temperatures, meaning that it can endure processing temperatures and the extreme heat generated by hot spots during device use. The strength of a material is measured by its elastic modulus. CVD SiC has an elastic modulus of 450 GPa (GigaPascals) that is around four times greater than the elastic modulus of silicon (107 GPa) and the elastic modulus of CVD SiC is nearly independent of temperature. Therefore, CVD SiC is around four times stronger than silicon. Because of the strength of CVD SiC the silicon wafer can be thinner than the current thickness of a silicon wafer used in manufacturing. In combination with the strong SiC layer, a thinner silicon wafer would be able to withstand handling during processing. This would be advantageous in the further scaling down of semiconductor devices.

Additionally, CVD SiC may exhibit a high purity (≧99.0005%) and will thus not contaminate the wafer or the processing chamber with intrinsic impurities. Also, the external impurities that cannot diffuse into the CVD SiC can easily be removed from the surface of the SiC. The diffusion coefficients of common metal impurities in CVD SiC at 1299.84° C. are very low and may not be able to diffuse into the silicon layer from the SiC layer. For example, Table I contrasts the diffusion coefficients of common metallic impurities in both CVD SiC and silicon.

| | Diffusion Coefficient in | Diffusion Coefficient in |
|---|---|---|
| | CVD SiC (cm²/sec at | Silicon (cm²/sec at |
| Metallic Impurity | 299.84° C.) | 1299.84° C. |
| Fe | 6.5 × 10⁻¹⁴ | 1 × 10⁻⁵ |
| Co | 1.3 × 10⁻¹³ | 3 × 10⁻⁵ |
| Cr | 6.3 × 10⁻¹⁴ | 5 × 10⁻⁶ |
| Au | 8.6 × 10⁻¹⁴ | 3 × 10⁻⁵ |

The bulk heat dissipation layer 220 may have a coefficient of thermal expansion (α) that is approximately equal to or greater than that of the semiconductor layer 210 so that stresses and fractures will not occur during changes in temperature, such as those during processing, between the two layers. If the semiconductor layer suffers fractures or dislocations the devices of the IC would be destroyed. Therefore, the coefficient of thermal expansion for a silicon semiconductor layer may be between around 2.0×10⁻⁶ per degree Celsius to around 3.0×10⁶ per degree Celsius. Again, CVD SiC has this ideal property because it has a coefficient of thermal expansion at room temperature of 2.20×10⁻⁶ per degree Celsius, similar to that of silicon that has a coefficient of thermal expansion at room temperature of 2.60×10⁻⁶ per degree Celsius.

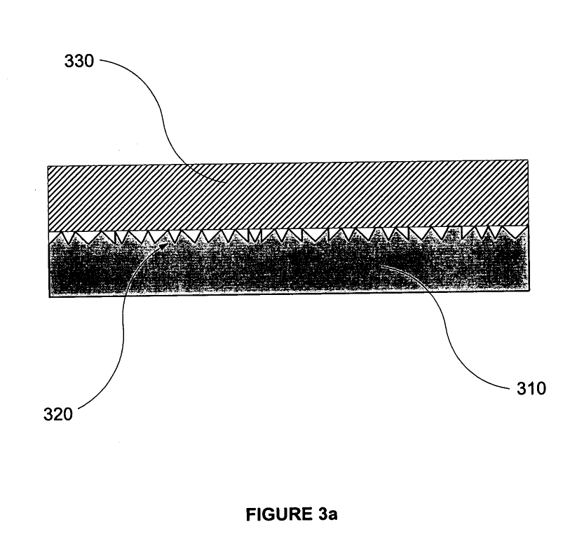

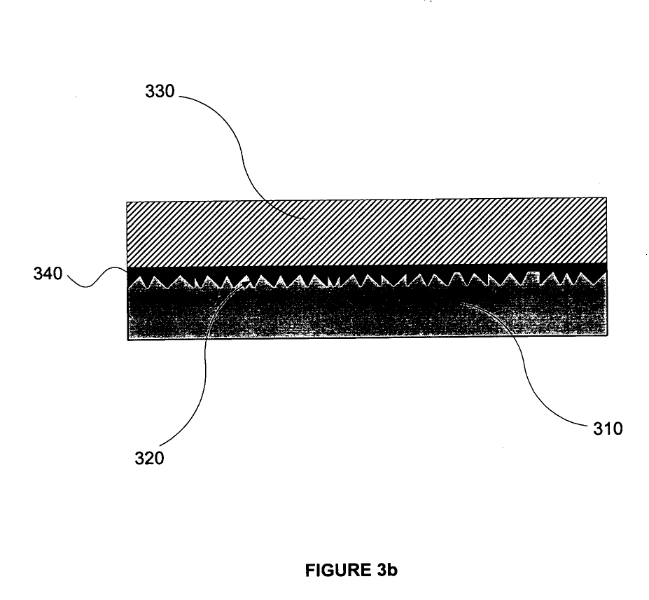

In an alternate embodiment of the present invention, as illustrated in FIG. 2b, a transition layer 250 is placed in between the semiconductor layer 210 and the bulk heat dissipation layer 220. The transition layer can be materials such as polysilicon, silicon nitride, and silicon dioxide that are stable and strong enough to withstand the IC processing conditions and will improve the adhesion between a silicon carbide wafer and a silicon wafer. The transition layer is may be between 100 Å-1000 Å in thickness and can be deposited by chemical vapor deposition (CVD). A transition layer is used to improve the adhesion of the bulk heat dissipation layer to the semiconductor layer, and in particular a silicon carbide layer to a silicon layer. In an embodiment, the transition layer is polysilicon on a bulk silicon carbide wafer. Silicon carbide is a very hard material that may be difficult to planarize to a perfectly smooth surface. Even after planarization, the bulk silicon carbide wafer 310, as illustrated in FIG. 3a, will have a jagged surface 320 to which the adhesion of the silicon wafer 330 may not be optimal because less of the surface area of the silicon wafer 330 is in contact with the bulk silicon carbide wafer 310. To create a smooth planarized surface to which the silicon wafer 330 can be adhered, the transition layer may be deposited to a thickness sufficient to fill the valleys of the rough surface. When a transition layer of silicon nitride is formed on the bulk silicon carbide wafer 310, as illustrated in FIG. 3b, it can be polished to form a smooth surface to which the silicon wafer 320 can adhere and form a strong bond. Please note that the dimensions of the jagged surface 320 and the thickness of the transition layer 330 are exaggerated for the purposes of explanation and should not be interpreted as being illustrative of actual dimensions.

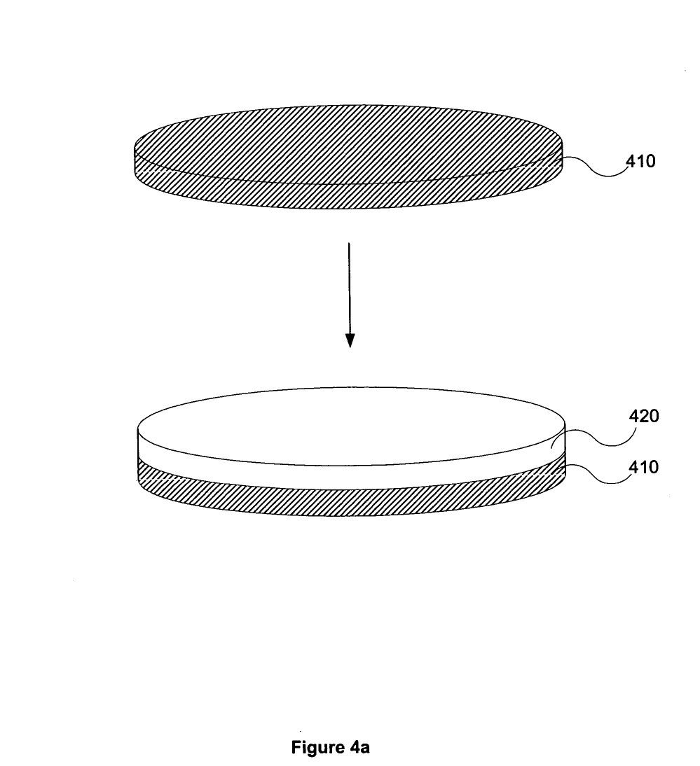

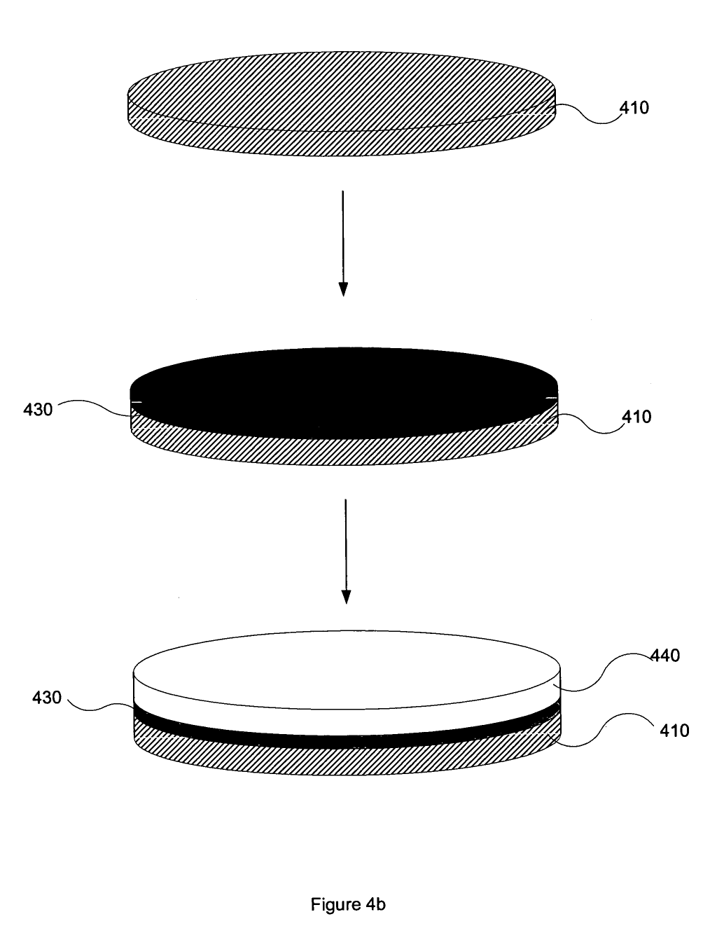

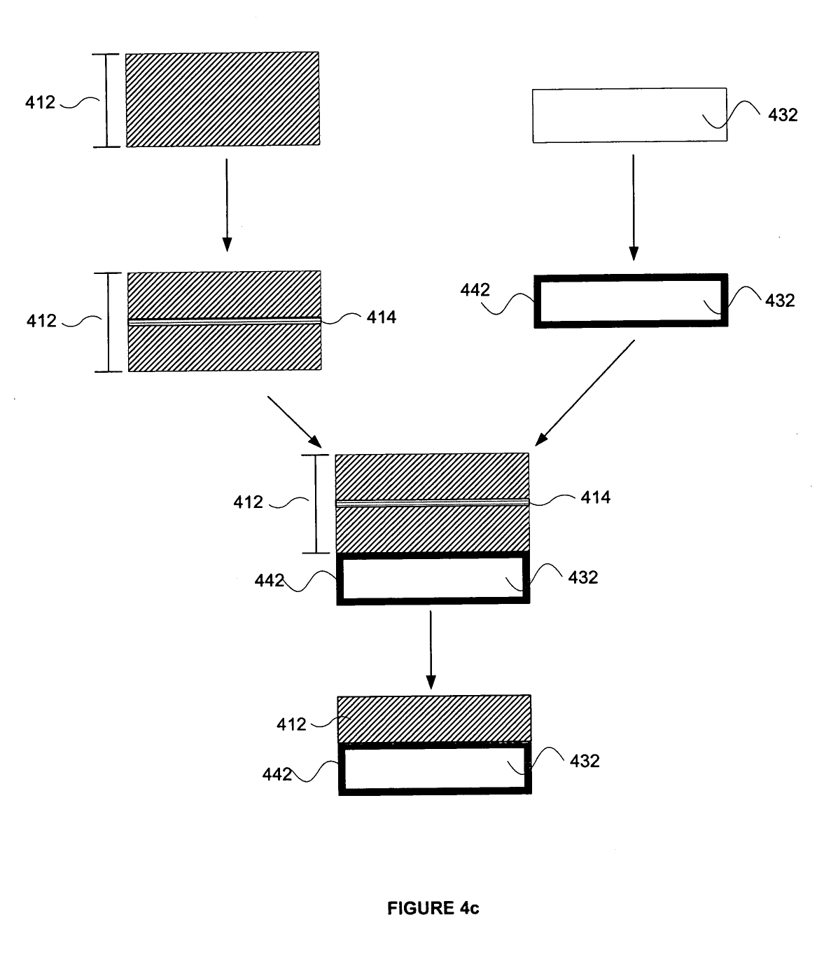

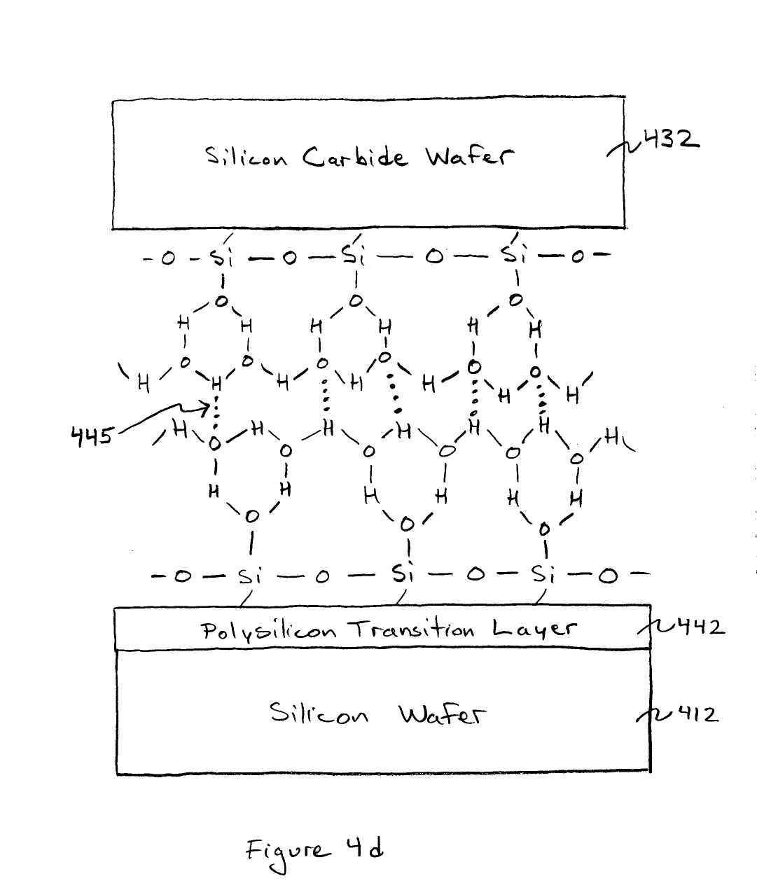

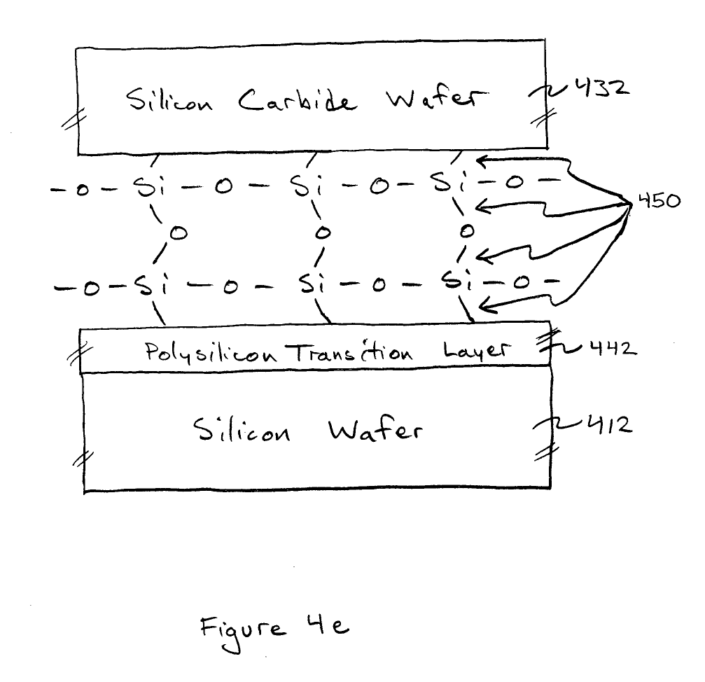

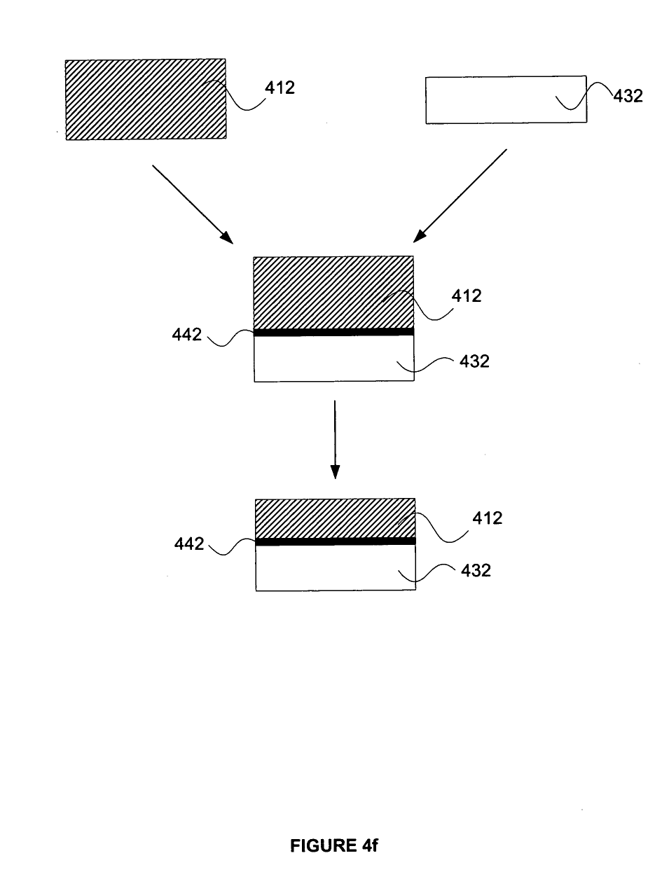

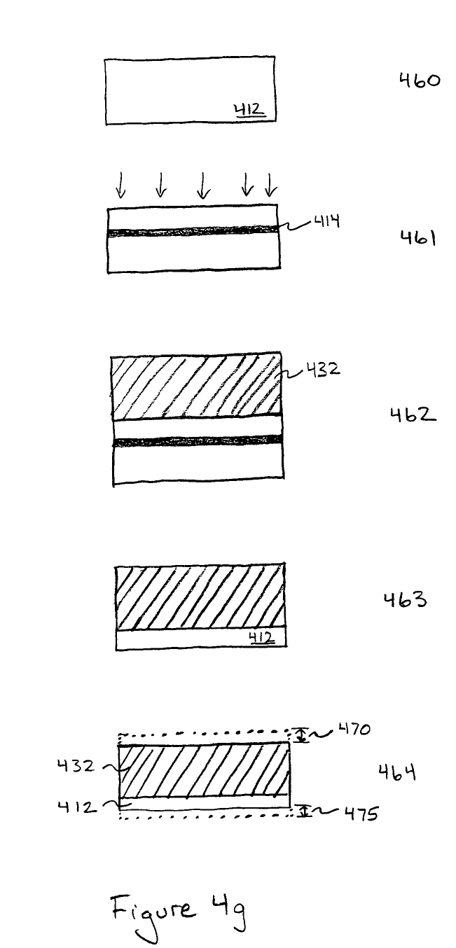

There are several methods by which a bulk heat dissipation substrate can be coupled to a semiconductor substrate. In one embodiment, the bulk heat dissipation substrate can be directly deposited on the semiconductor substrate. As illustrated in FIG. 4a, an untreated semiconductor wafer 410 is provided. A heat dissipation layer 420 is then deposited onto the semiconductor wafer 410. The deposition of the heat dissipation layer can be by chemical vapor deposition (CVD), atomic layer deposition, sputtering, or by any similar method. In an embodiment, where silicon carbide is deposited as the bulk heat dissipation substrate, CVD is one method of deposition. The bulk heat dissipation substrate can also be deposited by a direct bonding method where a wafer of the bulk heat dissipation substrate is bonded to a wafer of the semiconductor substrate. In this method, as illustrated in FIG. 4b, a transition layer 430 can be deposited onto the semiconductor wafer 410. The transition layer 430 can then be planarized to create a smooth surface to which a pre-formed bulk heat dissipation wafer 440 is bonded. There are two different direct bonding methods that may be employed. The first direct bonding method is the bond and split method and the second direct bonding method is the bond and grind back method.

One embodiment of the bond and split method is illustrated in FIG. 4c. A semiconductor substrate, and such as, for example, a silicon wafer 412, is provided. The silicon wafer 412 can then be implanted with a rare gas, such as hydrogen (H₂), to form a rare gas implant layer 414. In one embodiment where hydrogen is used, the hydrogen implant dose is approximately 5×10¹⁶ hydrogen atoms per square centimeter, and the implant energy is in the approximate range of 40-210 keV (kiloelectonVolts). In alternate embodiments, rare gases similar to hydrogen, such as helium, neon, krypton, and xenon, may be used individually or in combination to create the implant layer. The rare gas implant layer 414 is created to form a line along which the silicon wafer 412 can be split. The rare gas is implanted to a depth under the surface of the silicon wafer 412 necessary to create a silicon layer having the desired thickness after the splitting described later. This splitting method may also be used with other semiconductor materials. In a preferred embodiment, the thickness of the silicon wafer 412 after splitting is 750-800 μm. The bulk heat dissipation wafer 440 can be a silicon carbide (SiC) wafer 432 that, in one embodiment, may be formed by chemical vapor deposition. In an embodiment, the bulk heat dissipation substrate 440 has a transition layer 442. The entire SiC wafer 432 can be coated with a transition layer 442 such as silicon nitride, polysilicon, or similar materials. Alternately, just the surface of the SiC wafer 432 that may be bonded to the silicon wafer 412 can be coated with the transition layer 442. The transition layer 442 to which the silicon wafer 412 is to be bonded is then planarized to between 100 Å-1000 Å to optimize adhesion and bonding of the silicon carbide wafer 432 to the silicon wafer 412. In an embodiment, the silicon carbide wafer 432 can be bonded to the silicon wafer 412 with a polysilicon transition layer 442. The polysilicon transition layer 442 may have a thickness of approximately 1000 Å, and may be deposited by chemical vapor deposition, or in the alternative, sputtering or atomic layer deposition. As illustrated in FIG. 4d the polysilicon transition layer 442 will form weak chemical bonds 445 by Van der Walls forces between the silicon atoms of the polysilicon transition layer 442 and the silicon atoms of the silicon wafer 412. The entire substrate comprising the silicon wafer 412 and the polysilicon transition layer 442 bonded by Van der Walls forces to the silicon carbide wafer 432 can then be heated in the approximate range of 1 to 30 minutes and at a temperature in the approximate range of 100° C. to 600° C. As illustrated in FIG. 4e, the heat will cause strong covalent chemical bonds 450 to form between the silicon atoms of the silicon carbide wafer 432 and the silicon atoms of the polysilicon transition layer 442. The silicon wafer 412 can then be split along the line of the rare gas implant layer 414 due to the formation of tiny air blisters along the line of the implant when the silicon wafer 412 is heated, to form the substrate illustrated in FIG. 2b.

In an alternate embodiment, the semiconductor substrate 410 is directly bonded to the bulk heat dissipation substrate 440 using the bond and grind back method. This method is illustrated in FIG. 4f. A semiconductor substrate 410, such as a silicon wafer 412, is provided. A bulk heat dissipation substrate, typically a CVD SiC wafer 432, is provided. The silicon wafer 412 can then be bonded to the silicon carbide wafer 432 through a polysilicon layer 442. As described above, this polysilicon layer 442 can be deposited on the silicon carbide wafer 432 and then bonded by weak Van der Waals forces 445, as illustrated in FIG. 4d, to the silicon wafer 412 through the silicon atoms of the polysilicon layer 442 and the silicon atoms of the silicon wafer 412. The entire substrate is then heated at in the approximate range of 1 to 30 minutes and at a temperature in the approximate range of 100° C. to 600° C. to form covalent bonds 450, as illustrated in FIG. 4e, between the silicon atoms of the silicon carbide wafer 432, the polysilicon layer 442, and the silicon wafer 412. After bonding, the silicon wafer 412 is ground down to the desired thickness, which in an embodiment is 750-800 μm. In alternate embodiments, after being ground down, the silicon wafer 412 can have a thickness of greater than 800 μm or less than 750 μm. The silicon wafer 412 can be ground down by mechanical means such as by a diamond abrasive polishing head or by chemical mechanical polishing. In chemical mechanical polishing, a chemical slurry containing abrasives and oxidizing agents is typically applied to the silicon wafer 412 and mechanical pressure is applied to the silicon wafer 412 by a rotating pad.

In an alternate embodiment, as illustrated in FIG. 4g, the heat dissipation substrate can be formed by providing a semiconductor wafer, such as a silicon wafer 412, at block 460. The silicon wafer is then implanted with a rare gas, such as hydrogen, to form a rare gas implant layer 414 at block 461. Above the silicon wafer 412 a bulk heat dissipation layer, such as a silicon carbide layer 432, may then be deposited at block 462 by chemical vapor deposition or any similar method of deposition. At block 463 the silicon wafer 412 is split along the rare gas implant layer. At block 464 the silicon wafer 412 is polished by a thickness 470 and the silicon carbide layer 432 is polished by a thickness 475. The thickness 470 and the thickness 475 may be any thickness sufficient to obtain the desired thickness of the substrate formed of the silicon wafer 412 and the silicon carbide layer 432.

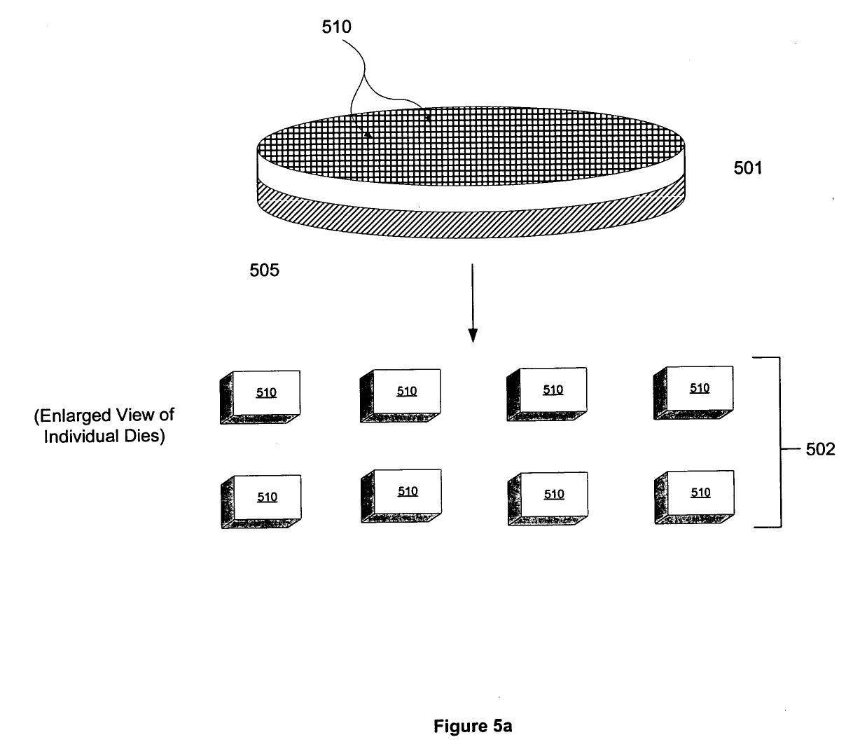

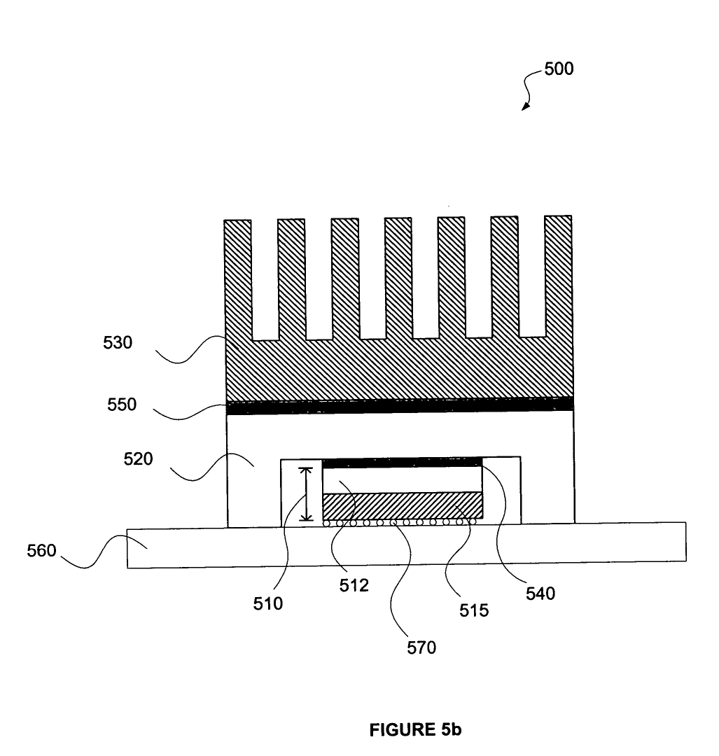

Wafer substrates that are fabricated by the above method, and have a semiconductor substrate on a bulk heat dissipation substrate, are subsequently cut into dies after the IC devices on the wafers have been fabricated. FIG. 5a illustrates this process. The fabrication of the IC devices and interconnects on a wafer 505 can be designed so that several dies 510 are patterned onto the wafer 505 at 501. The dies 510 on the wafer 505 are then cut at 502 into several individual dies 510. An individual die 510 can then become part of a microelectronic package 500 as illustrated in FIG. 5b that typically includes an individual die 510, a heat sink 520, and a heat spreader 530. The backside of the die the bulk heat dissipation substrate 512 is positioned on a silicon substrate 515 that is attached to the heat sink. The heat sink 520 is typically a conductive metal such as aluminum or copper and will remove heat from the backside of the die. The heat sink is coupled to the die by a first thermal interface layer 540 (TIM). The heat spreader 530 is coupled to the heat sink 520 by a second TIM 550. A TIM is usually a grease or a gel containing metal particles to improve the heat transfer between the die 510 and the heat sink 520 and the heat spreader 530. The die 510 can be enclosed by the heat sink 520 on a package substrate 560. The die 510 can be coupled to the package substrate 560 by solder bumps 570.

The coupling of a bulk heat dissipation substrate to a semiconductor substrate is a cost effective and practical method of improving the heat dissipation characteristics of an IC die. Additionally, the bulk heat dissipation layer provides improved heat dissipation of “hot spots” because it is directly coupled to the semiconductor device layer. Also, because it is a bulk layer there is a greater mass of material into which the heat can dissipate, and the added benefit of adding strength to the semiconductor layer. The strength and thickness of the layer also provides the advantage of providing a portion of the substrate that can be handled by the fabrication tools during manufacturing to decrease the likelihood of damaging the semiconductor device layer.

Several embodiments of the invention have thus been described. However, those of ordinary skill in the art will recognize that the invention is not limited to the embodiments described, but can be practiced with modification and alteration within the scope and spirit of the appended claims that follow.

1. A process comprising:
providing a semiconductor substrate; and
coupling said semiconductor substrate directly to a bulk heat dissipation substrate having a thermal conductivity greater than that of said semiconductor substrate.

2. The process of claim 1 wherein said bulk heat dissipation substrate is silicon carbide.

3. The process of claim 1 wherein said bulk heat dissipation substrate is a material that removes heat from the semiconductor substrate.

4. The process of claim 1 wherein said coupling comprises:
forming a splitting layer within the semiconductor substrate;
bonding said semiconductor substrate chemically to said bulk heat dissipation substrate; and
splitting said semiconductor substrate along said splitting layer.

5. The process of claim 4 wherein forming said splitting layer comprises implanting said semiconductor substrate with a rare gas to form a rare gas implant layer.

6. The process of claim 5 wherein said rare gas is hydrogen.

7. The process of claim 1 wherein said coupling comprises:
bonding said semiconductor substrate chemically to said bulk heat dissipation substrate; and
grinding back said semiconductor substrate.

8. The process of claim 1 wherein said coupling comprises:
depositing said bulk heat dissipation substrate directly on said semiconductor substrate.

9. The process of claim 8 wherein said depositing of said bulk heat dissipation substrate comprises chemical vapor deposition.

10. The process of claim 1 further comprising forming a transition layer on said bulk heat dissipation substrate prior to said coupling.

11. The process of claim 10 wherein said transition layer is silicon nitride.

12. The process of claim 10 wherein said transition layer is polysilicon.

13. The process of claim 12 further comprising bonding said polysilicon transition layer to said semiconductor substrate.

14. The process of claim 13 wherein bonding said polysilicon transition layer to said semiconductor substrate comprises:
forming weak bonds between said polysilicon layer and said silicon layer; and
heating said polysilicon layer and said silicon layer to create covalent bonds between said polysilicon layer and said silicon layer.

15. A process comprising:
providing a silicon wafer;
implanting said silicon wafer with hydrogen to form a hydrogen implant layer within said silicon wafer;
depositing a silicon carbide layer on said silicon wafer by chemical vapor deposition;
splitting said silicon wafer along said implant layer to form a silicon layer on which said silicon carbide layer is deposited;
polishing said silicon layer; and
polishing said silicon carbide layer.

16. The process of claim 15 further comprising depositing said silicon carbide layer to a thickness in the approximate range of 0.5 mm-1.0 mm.

17. The process of claim 15 further comprising polishing said silicon carbide layer to a thickness in the approximate range of 750-800 μm.

18. A substrate comprising:
a semiconductor wafer; and
a bulk heat dissipation wafer in contact with said semiconductor wafer and having a higher thermal conductivity than said semiconductor wafer.

19. The substrate of claim 18 wherein said semiconductor wafer comprises silicon.

20. The substrate of claim 18 wherein said bulk heat dissipation wafer comprises silicon carbide formed by chemical vapor deposition.

21. The substrate of claim 18 wherein said semiconductor wafer is covalently bonded to said bulk heat dissipation wafer.

22. The substrate of claim 18 wherein the elastic modulus of said bulk heat dissipation wafer is greater than the elastic modulus of said semiconductor wafer.

23. The substrate of claim 18 wherein the thermal expansion coefficient of said semiconductor wafer is approximately equal to the thermal expansion coefficient of said bulk heat dissipation wafer.

24. The substrate of claim 18 further comprising a transition layer between said semiconductor wafer and said bulk heat dissipation wafer.

25. A heat dissipation device comprising:
a silicon carbide wafer having a thickness greater than 100 μm;
a transition layer comprising polysilicon coated on said silicon carbide wafer, wherein said transition layer is planarized on a first side; and
a silicon wafer covalently bound to said first side of said transition layer.

26. The device of claim 25 wherein said silicon wafer has a thickness of between 750 μm and 800 μm.

27. The device of claim 25 wherein said silicon carbide wafer has a thickness of between 750 μm and 800 μm.

28. A microelectronic package comprising:
a die comprising a silicon substrate having a first surface having devices formed thereon and a second surface chemically bonded to a bulk silicon carbide substrate; and
a heat sink.

29. The system of claim 28 further comprising a first thermal interface material between said silicon carbide and said heat sink.

30. The system of claim 28 wherein said die further comprises a transition layer between said silicon layer and said silicon carbide layer.
